(19) United States
(12) Patent Application Publication
(10) Pub. No.: US 2003/0087510 A1
(43) Pub. Date: May 8, 2003

(54) Method of forming MOS transistor graded junctions using multiple implant of low diffusion specie, and a device formed thereby

(76) Inventor: Aikwo Eric Chen, San Jose, CA (US)

Correspondence Address: GARY CARY WARE & FREIDENRICH LLP, 1755 EMBARCADERO ROAD, PALO ALTO, CA, 94303-3340, US

(21) Appl. No.: 10/007,548

(22) Filed: Nov. 6, 2001

(51) Int. Cl. H01L 21/425

(52) U.S. Cl. 438/529

(57) ABSTRACT

A method of forming a graded junction in silicon includes implanting a first impurity specie into a silicon substrate, annealing the silicon to drive the implanted first specie deeper into the silicon, implanting a second impurity specie into the silicon substrate, and annealing the silicon to drive the second specie deeper into the silicon. Both first and second species, which can be the same or different species, have low silicon diffusion coefficient(s), such as Arsenic or Antimony. At least some of the implanted first specie is driven further into the silicon than any of the implanted second specie. The first specie has a lower dosage and greater implant energy to help form a graded junction, and the second specie has a greater dosage and lower implant energy for creating a high impurity concentration at the surface of the substrate.

### FIELD OF THE INVENTION

The present invention relates to semiconductor manufacturing, and more particularly to the formation of graded junctions for MOS transistors.

### BACKGROUND OF THE INVENTION

Formation of graded P-N junctions in silicon is well known in the art of making MOS transistors. Source and drain regions are typically formed in a silicon substrate (or a well in the substrate), which is doped to have one conductivity type (P or N), by implanting impurities to form regions in the substrate (or well) having the other conductivity type. For example, with silicon doped to have P type conductivity, impurities are implanted in select regions of the silicon to cause those regions to have N type conductivity. P-N or N-P junctions are formed at the boundaries of these regions.

An ideal junction should have 1) a graded junction doping profile, 2) a high surface doping concentration, and 3) a shallow junction depth with minimal side diffusion. A graded junction means that the dopant profile gradually tails off at the boundary of the source or drain regions, which will sustain higher reverse bias voltages without being damaged (i.e. higher junction breakdown voltage). A high surface doping concentration forms a better ohmic contact at the surface of the substrate. The shallow junction depth with little side diffusion reduces the size of the regions, and thus the overall dimensions of the MOS device.

Traditionally, MOS N+ graded junctions have been formed by implanting both Phosphorus and Arsenic (high dosage) into the surface of a P doped silicon substrate. Then, the Phosphorus and Arsenic are thermally driven deeper into the silicon using an anneal process (e.g. Rapid Thermal Anneal—RTA) until the desired depth and surface concentration are achieved. Arsenic has a low diffusion coefficient which results in a very steep doping profile gradient, and thus forms a high dopant concentration at the substrate surface. Phosphorus is driven deeper into the substrate because of its much higher diffusion coefficient, and has a less steep doping profile gradient whereby its concentration tails off more gradually as the depth increases to form the graded junction.

With the presence of both Phosphorus and Arsenic, tails in the doping profiles are formed due to the so called Transient Enhanced Diffusion effect. Impurities are thermally driven through silicon in two modes: interstitial (through the interstitial of the silicon crystalline lattice) and substitutional (through the lattice sites of the silicon crystalline lattice). Implants actually damage the lattice, whereby such defects (interstitial type defects) in the lattice actually enhance the process of thermally driving impurities into the silicon. Arsenic is driven through silicon in the substitutional mode, and Phosphorus is driven in both modes. Thus, the defects in the silicon caused by the Arsenic and Phosphorus combination increase the junction depth and side diffusion (lateral expansion of the source/drain regions). Punch-through problems are induced which are problematic for smaller devices (e.g. 0.13 μm technology and below) because it is difficult or impossible to scale down the junction size. Moreover, for manufacturing methods that require long and/or high temperature thermal processes after the Phosphorus implantation is done, there is a further undesired expansion of the junction depth during these later process steps.

There is a need for an improved process of forming a junction that is sufficiently graded for a higher junction breakdown voltage, that has a sufficiently high surface doping concentration for a good ohmic contact, and has a shallow junction depth with minimal side diffusion for smaller device geometries.

### SUMMARY OF THE INVENTION

The present invention is a method of forming a graded junction in silicon, and includes the steps of implanting a first impurity specie into a region of silicon, wherein the silicon has a first conductivity type and the first specie has a silicon diffusion coefficient that does not exceed that of arsenic, implanting a second impurity specie into the region of the silicon, wherein the second specie has a silicon diffusion coefficient that does not exceed that of arsenic, and annealing the silicon to drive at least some of the implanted first and second species deeper into the silicon. At least a portion of one of the implanted first and second species is driven further into the silicon than any of the other of the implanted first and second species. The implanted first and second species cause the region of silicon to have a second conductivity type different from the first conductivity type.

In another aspect of the present invention, the method of forming a graded junction in silicon includes the steps of implanting a first impurity specie into a region of silicon, wherein the silicon has a P conductivity type and the first specie is one of arsenic and antimony, implanting a second impurity specie into the region of the silicon, wherein the second specie is one of arsenic and antimony, and annealing the silicon to drive at least some of the implanted first and second species deeper into the silicon. At least a portion of one of the implanted first and second species is driven further into the silicon than any of the other of the implanted first and second species. The implanted first and second species cause the region of silicon to have an N conductivity type.

In yet one more aspect of the present invention, a semiconductor device includes a semiconductor substrate having a surface and a first conductivity type, a junction region in the substrate and first and second impurity species implanted into the junction region, wherein the first and second species have silicon diffusion coefficients that do not exceed that of arsenic. At least a portion of one of the implanted first and second species is disposed deeper into the silicon from the surface than any of the other of the implanted first and second species. The implanted first and second species cause the region of silicon to have a second conductivity type different from the first conductivity type.

Other objects and features of the present invention will become apparent by a review of the specification, claims and appended figures.

### BRIEF DESCRIPTION OF THE DRAWINGS

FIG. 1 is a graph showing the one dimension dopant concentration in the silicon after the first Arsenic implant step of the present invention.

FIG. 2 is a graph showing the one dimension dopant concentration in the silicon after the first Arsenic anneal/diffusion step of the present invention.

FIG. 3 is a graph showing the one dimension dopant concentrations in the silicon after the second Arsenic implant step of the present invention.

FIG. 4 is a graph showing the one dimension dopant concentrations in the silicon after the second Arsenic anneal/diffusion step of the present invention.

FIG. 5 is a graph showing the one dimension aggregate dopant concentration in the silicon after the second Arsenic anneal/diffusion step of the present invention.

### DETAILED DESCRIPTION OF THE PREFERRED EMBODIMENTS

The present invention is an improved method of forming a graded junction, which includes implanting and diffusing/annealing an impurity specie with a low diffusion coefficient (diffuses slowly) into a silicon substrate, multiple times. Arsenic and Antimony are examples of impurity species with low diffusion coefficients. Arsenic will be used in the following description of the method of the present invention.

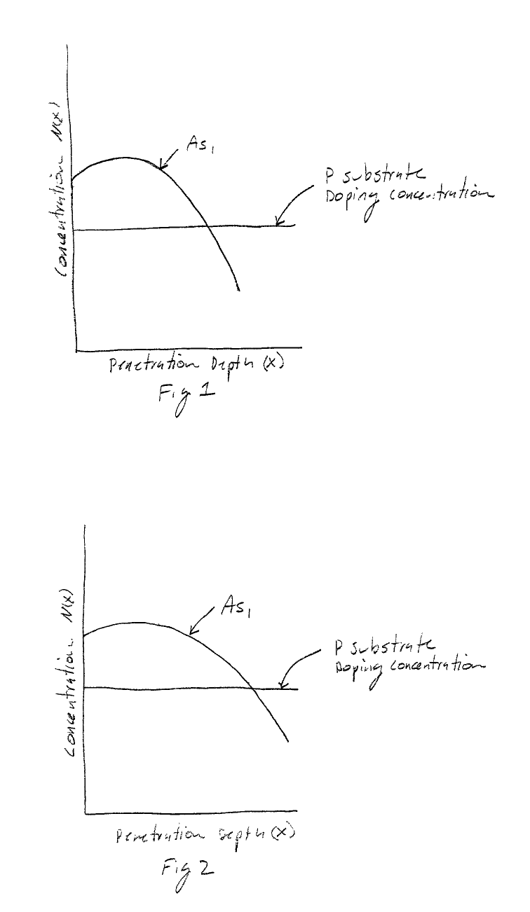

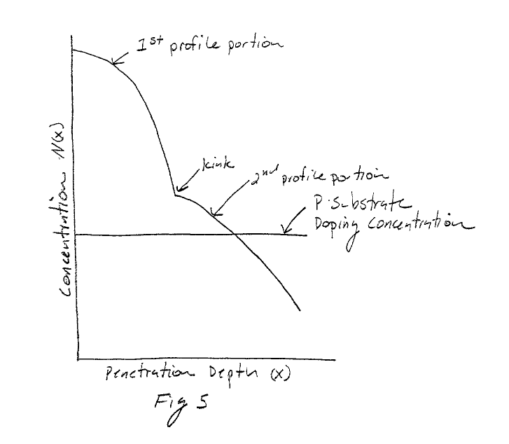

FIGS. 1-4 graphically illustrate one-dimensional junction doping concentration profiles as a function of penetration depth (x), achieved during a double implant/diffusion method according to the present invention. Penetration depth (x) is the vertical distance from the surface, and N(x) is the Arsenic doping concentration at (x). Penetration depth (x) can also be the horizontal distance from the implant edge, since the concentration profiles are similar for both horizontal and vertical diffusion.

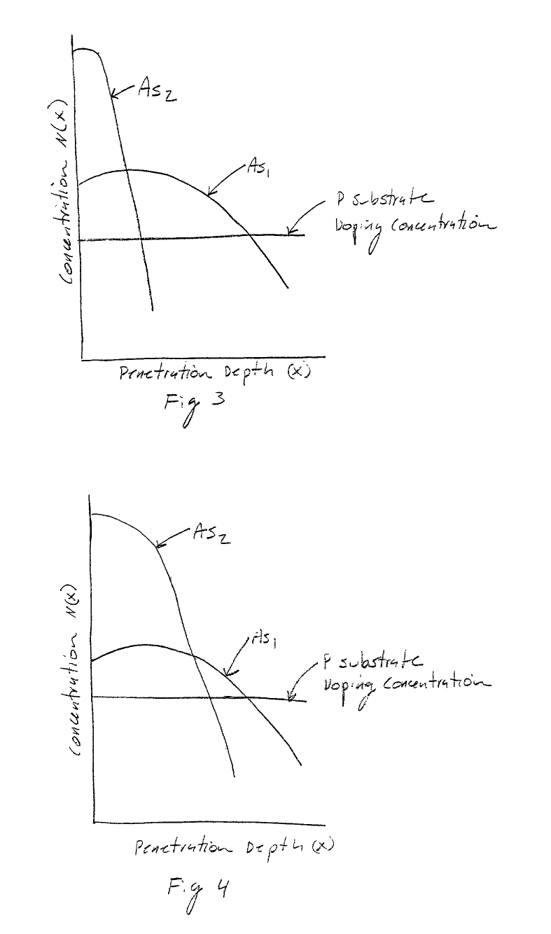

A first Arsenic implant is performed, preferably using a relatively low dosage (e.g. approximately 1 to 2 E14 cm⁻³) and a relatively high implant energy (e.g. approximately 20 to 100 KeV). The resulting concentration profile of the implanted Arsenic (As₁) is illustrated in FIG. 1. The high implant energy results in a relatively level Arsenic concentration near the surface, which drops off gradually until it drops below the P doped concentration of the silicon substrate. A first diffusion/anneal process is then performed to drive the implanted Arsenic deeper into the silicon. Preferably, a Rapid Thermal Anneal (RTA) process is used (e.g. RTA at 1020° C., for approximately 10 seconds). The concentration profile of the first implanted Arsenic is extended deeper into the silicon by the first diffusion/anneal process, and creates a graded junction as the concentration profile meets the P substrate doping concentration level, as shown in FIG. 2.

Next, a second Arsenic implant is performed, preferably using a relatively high dosage (e.g. 2.5 to 5.5 E15 cm⁻³) and relatively low implant energy (e.g. approximately 15 KeV). The resulting concentration profile of the second implanted Arsenic (As₂) is illustrated in FIG. 3, along with the diffused/annealed concentration profile of the first implanted Arsenic (As₁). Because of the higher dosage and lower implant energy, the concentration of the second implanted Arsenic (As₂) near the substrate surface is much higher than that of the first implanted Arsenic (As₁), but falls off more rapidly until it drops below the P-substrate doping concentration of the silicon. A second diffusion/anneal process then performed to activate and drive the second Arsenic implant (As₂) deeper into the silicon (as well as the first Arsenic implant (As₁)). Preferably, a Rapid Thermal Anneal (RTA) process is used (e.g. RTA 1020 C., for approximately 30 seconds). The concentration profile of the second implanted Arsenic is extended deeper into the silicon by the second diffusion/anneal process, but does not extend as deep into the substrate as the first implanted Arsenic. In other words, the tail end of the As₁ concentration profile extends deeper into the silicon before reaching the P-substrate doping concentration than does the tail end of the (As₂) concentration profile.

When the (As₁) and (As₂) concentrations are considered together, the (As₁) concentration profile extends deeper into the silicon to provide a sufficiently graded junction, while the (As₂) implant/anneal provides a high surface concentration. FIG. 5 illustrates the aggregate concentration profile for both As₁ and As₂ implants, which includes a first portion (formed mainly by the As₂ implant) and a second portion (formed mainly by the As₁ implant). The first portion has a relatively high concentration which drops off steeply. The second portion has a lower concentration that drops of much more moderately. A ‘kink’ is formed where the two portions meet, and signifies the point at which the slope of the concentration curve dramatically decreases.

The double implant/anneal of a low diffusion material such as Arsenic provides two degrees of freedom, whereby the first and second implant/anneal processes can be independently optimized to provide both the desired graded junction and the high surface concentration, all with a shallow junction depth and limited side diffusion. The combined doping profiles produce a more graded junction than that of only a single implant anneal/diffusion process with similar junction depth and similar surface concentration. Moreover, this process is quite suitable for devices whose process flows include long and high temperature cycles after the Arsenic implants. The low diffusion coefficient of the Arsenic better preserves the integrity, size and concentration of the graded junction. In fact, if long and high temperature cycles exist in the process flow, the first Arsenic implant can be performed before those thermal cycles and use them to diffuse the first implanted Arsenic, while the second Arsenic implant/anneal can be performed after those thermal cycles.

It should be clear that lower implant energies could be used if high dosages and/or longer anneal steps are employed, and vice versa. The key to this invention is the use of multiple implants of low diffusion coefficient species with varying dosages and implant energies so that the one implant extends deeper into the substrate than the second to produce a moderately sloped concentration profile, and the first and second implants combine to achieve a sufficiently high surface concentration at the substrate surface, while the overall junction area is sufficiently small.

Arsenic and Antimony are ideal low diffusion coefficient species for N type junctions in P doped silicon. The calculation of silicon diffusion coefficients is discussed in Silicon VLSI Technology, Fundamentals, Practice and Modeling, James Plummer, Michael Deal, and Peter Griffin, Prentice Hall, Inc, 2000, pages 406-413. Diffusivity D for N type dopants such as Arsenic and Antimony actually varies with dopant concentration and temperature, and can be expressed as follows:

D=D⁰.0·exp(−D⁰.E/kT)+(n/nᵢ)·D⁻.0·exp(−D⁻.E/kT)+(n/nᵢ)²·D⁼.0·exp(−D⁼.E/kT) (1)

where D⁰.0 and D⁰.E are neutral charge diffusivity parameters, D⁻.0 and D⁻.E are single charge diffusivity parameters, D⁼.0 and D⁼.E are double charge diffusivity parameters, n is the dopant dosage, nᵢ is the intrinsic dopant of the silicon (where n/nᵢ=1, if n<nᵢ), and T is temperature.

Diffusivity parameters for the N type dopants Arsenic, Antimony and Phosphorus are:

| | Arsenic | Antimony | Phosphorus |
|---|---|---|---|
| D⁰.0 (cm²/sec) | 0.011 | 0.214 | 3.85 |
| D⁰.E (eV) | 3.44 | 3.65 | 3.66 |
| D⁻.0 (cm²/sec) | 31.0 | 15.0 | 4.44 |
| D⁻.E (eV) | 4.15 | 4.08 | 4.0 |
| D⁼.0 (cm²/sec) | — | — | 44.2 |
| D⁼.E (eV) | — | — | 4.37 |

To illustrate the low diffusivity of Arsenic and Antimony, compared to the more diffusive phosphorus, the diffusivities of these three dopants are calculated using equation 1, the listed diffusivity parameters, a temperature of 1000° C., and a dosage n of 1.0 E+21 (nᵢ=7.14E18):

D_{Arsenic}=2.64231E-16+1.61165E-13=1.6143E-13 cm²sec. (2)

D_{Antimony}=7.57857E-16+1.47618E-13=1.4838E-13 cm²/see. (3)

D_{Phosphorus}=1.24464E-14+9.06072E-14+4.33137E-12=4.4344E-12 cm²/sec. (4)

The above calculations show that the diffusion coefficients for arsenic and antimony are approximately an order of magnitude smaller than that of phosphorus. Thus, for the purposes of this disclosure, any specie that has a diffusion coefficient that is approximately equal to or less than that of Arsenic is considered a low diffusion coefficient specie.

Additional implant/anneal processes can be used to offer even more degrees of freedom to tailor the doping profile of the graded junction. For example, in a triple implant/anneal process, the first implant/diffusion steps can be used to produce the desired graded junction, the second implant/diffusion steps can be used to produce the desired side diffusion of the junction, and the third implant/diffusion steps can be used to produce the desired surface concentration.

It is to be understood that the present invention is not limited to the embodiment described above and illustrated herein, but encompasses any and all variations falling within the scope of the appended claims. For example, two different low diffusion coefficient species can be combined in the same junction, where one low diffusion coefficient specie is used in the first implant/anneal step (e.g. arsenic), and a second (different) low diffusion coefficient specie is used in the second implant/anneal step (e.g. antimony). Further, it is within the scope of the present invention to omit the first anneal process, whereby two low diffusion coefficient specie implants are performed, followed by one or more anneal processes. Moreover, as is apparent from the claims, not all method steps need be performed in the exact order illustrated or presented in the claims, but rather in any order that allows the proper formation of the graded junction of the present invention. For example, the order of implants could be reversed, where the implant (As₁) driven deeper to form the graded junction could be implanted after the implant (As₂) used to form the high surface concentration.

What is claimed is:

1. The method of forming a graded junction in silicon, comprising the steps of:
implanting a first impurity specie into a region of silicon, wherein the silicon has a first conductivity type and the first specie has a silicon diffusion coefficient that does not exceed that of arsenic;
implanting a second impurity specie into the region of the silicon, wherein the second specie has a silicon diffusion coefficient that does not exceed that of arsenic; and
annealing the silicon to drive at least some of the implanted first and second species deeper into the silicon;
wherein at least a portion of one of the implanted first and second species is driven further into the silicon than any of the other of the implanted first and second species, and wherein the implanted first and second species cause the region of silicon to have a second conductivity type different from the first conductivity type.

2. The method of claim 1, further comprising the step of:
annealing the silicon after the implantation of the first specie and before the implantation of the second specie to drive at least some of the implanted first specie deeper into the silicon.

3. The method of claim 1, wherein an implant energy of the one of the implanted first and second species is greater than an implant energy of the other of the implanted first and second species.

4. The method of claim 3, wherein a dosage of the one of the implanted first and second species is less than that of the other of the first and second species.

5. The method of claim 1, wherein the first specie is the same as the second specie.

6. The method of claim 5, wherein the first and second species are both arsenic or both antimony.

7. The method of claim 1, wherein the first specie is different from the second specie.

8. The method of claim 7, wherein the first specie is one of arsenic and antimony, and the second specie is the other one of arsenic and antimony.

9. The method of claim 1, further comprising the steps of:
implanting a third impurity specie into the region of the silicon, wherein the third specie has a silicon diffusion coefficient that does not exceed that of arsenic; and
annealing the silicon to drive at least some of the implanted third specie deeper into the silicon;
wherein at least some of the one of the implanted first and second species is driven further into the silicon than any of the implanted third specie.

10. The method of claim 1, wherein a concentration profile of the one of the implanted first and second species in the silicon extends further into the silicon than a concentration profile of the other of the implanted first and second species.

11. The method of claim 1, wherein a concentration profile of the implanted first and second species as a function of region depth in the silicon includes a kink point at which a slope of the concentration profile significantly changes.

12. The method of claim 11, wherein the concentration profile has a first portion with a higher concentration and steeper slope than that of a second portion of the concentration profile, and wherein the kink point is between the first and second concentration profile portions.

13. A method of forming a graded junction in silicon, comprising the steps of:
implanting a first impurity specie into a region of silicon, wherein the silicon has a P conductivity type and the first specie is one of arsenic and antimony;
implanting a second impurity specie into the region of the silicon, wherein the second specie is one of arsenic and antimony; and
annealing the silicon to drive at least some of the implanted first and second species deeper into the silicon;
wherein at least a portion of one of the implanted first and second species is driven further into the silicon than any of the other of the implanted first and second species, and wherein the implanted first and second species cause the region of silicon to have an N conductivity type.

14. The method of claim 13, further comprising the step of:
annealing the silicon after the implantation of the first specie and before the implantation of the second specie to drive at least some of the implanted first specie deeper into the silicon.

15. The method of claim 13, wherein an implant energy of the one of the implanted first and second species is greater than an implant energy of the other of the implanted first and second species.

16. The method of claim 15, wherein a dosage of the one of the implanted first and second species is less than that of the other of the first and second species.

17. The method of claim 15, wherein the first and second species are both arsenic or both antimony.

18. The method of claim 15, wherein the first specie is one of arsenic and antimony, and the second specie is the other one of arsenic and antimony.

19. The method of claim 15, further comprising the steps of:
implanting a third impurity specie into the region of the silicon, wherein the third specie is one of arsenic and antimony; and
annealing the silicon to drive at least some of the implanted third specie deeper into the silicon;
wherein at least some of the one of the implanted first and second species is driven further into the silicon than any of the implanted third specie.

20. The method of claim 13, wherein a concentration profile of the one of the implanted first and second species in the silicon extends further into the silicon than a concentration profile of the other of the implanted first and second species.

21. The method of claim 13, wherein a concentration profile of the implanted first and second species as a function of region depth in the silicon includes a kink point at which a slope of the concentration profile significantly changes.

22. The method of claim 21, wherein the concentration profile has a first portion with a higher concentration and steeper slope than that of a second portion of the concentration profile, and wherein the kink point is between the first and second concentration profile portions.

23. A semiconductor device, comprising:
a semiconductor substrate having a surface and a first conductivity type;
a junction region in the substrate; and
first and second impurity species implanted into the junction region, wherein the first and second species have silicon diffusion coefficients that do not exceed that of arsenic;
wherein at least a portion of one of the implanted first and second species is disposed deeper into the silicon from the surface than any of the other of the implanted first and second species, and wherein the implanted first and second species cause the region of silicon to have a second conductivity type different from the first conductivity type.

24. The device of claim 23, wherein a dosage of the one of the first and second species in the region is less than that of the other of the first and second species.

25. The device of claim 23, wherein the first specie is the same as the second specie.

26. The device of claim 25, wherein the first and second species are both arsenic or both antimony.

27. The device of claim 23, wherein the first specie is different from the second specie.

28. The device of claim 27, wherein the first specie is one of arsenic and antimony, and the second specie is the other one of arsenic and antimony.

29. The device of claim 23, further comprising:
a third specie implanted into the junction region and having a silicon diffusion coefficient that does not exceed that of arsenic;
wherein at least a portion of one of the implanted first and second species is disposed deeper into the silicon from the surface than any of the implanted third specie.

30. The device of claim 23, wherein a concentration profile of the one of the implanted first and second species as a function of junction region depth in the silicon extends further into the silicon than a concentration profile of the other of the implanted first and second species.

31. The device of claim 23, wherein a concentration profile of the implanted first and second species as a function of junction region depth in the silicon includes a kink point at which a slope of the concentration profile significantly changes.

32. The device of claim 31, wherein the concentration profile has a first portion with a higher concentration and steeper slope than that of a second portion of the concentration profile, and wherein the kink point is between the first and second concentration profile portions.
